(19) United States
(12) Patent Application Publication
(10) Pub. No.: US 2006/0176924 A1
(43) Pub. Date: Aug. 10, 2006

(54) Semiconductor light emitting device having effective cooling structure and method of manufacturing the same

(75) Inventors: Ki-sung Kim, Hwaseong-si (KR); Jun-ho Lee, Seongnam-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: SAMSUNG ELECTRONICS CO., LTD., Suwon-si (KR)

(21) Appl. No.: 11/345,333

(22) Filed: Feb. 2, 2006

(30) Foreign Application Priority Data
Feb. 5, 2005 (KR) 10-2005-0010993

(51) Int. Cl. H01S 5/00

(52) U.S. Cl. 372/50.11

(57) ABSTRACT

A semiconductor light emitting device having a high heat emission efficiency and a method of manufacturing the same without reducing the light emission efficiency are provided. The semiconductor light emitting device includes a substrate, a thermal spreading layer formed on the substrate and patterned with predetermined gaps, a planarizing layer having a planarizing surface covering the thermal spreading layer, and a light emitting unit formed on the planarizing layer.

### CROSS-REFERENCE TO RELATED PATENT APPLICATION

This application claims the benefit of Korean Patent Application No. 10-2005-0010993, filed on Feb. 5, 2005, in the Korean Intellectual Property Office, the disclosure of which is incorporated herein in its entirety by reference.

### BACKGROUND OF THE DISCLOSURE

1. Field of the Disclosure

The disclosure relates to a semiconductor light emitting device having an effective cooling structure and a method of manufacturing the same, and more particularly, to a semiconductor light emitting device having an effective cooling structure which can be manufactured by a simple method without reducing the light emitting efficiency, and a method of manufacturing the same.

2. Description of the Related Art

The current trend for light emitting devices, such as surface light emitting semiconductor devices, is towards higher outputs and larger diameter laser beams. As the output of a laser device and the diameter of its beam increase, more heat is generated in the device. Therefore, there is a need for a new cooling structure that can effectively remove heat generated by the laser device.

FIG. 1 is a cross-sectional view illustrating a conventional cooling structure of a light emitting device. The light emitting device of FIG. 1 is a high output Vertical External Cavity Surface Emitting Laser (VECSEL) in which a gain region is increased using an external mirror 130. Referring to FIG. 1, a conventional cooling structure includes a metal pad layer 105 formed on a sub-mount 100, with a laser mounted on the metal pad layer 105. The metal pad layer 105 is joined to a lower metal contact layer 114a of the laser device. In this cooling structure, heat generated at an active layer 112 which generates light is transferred to the sub-mount 100 though the lower metal contact layer 114a and the metal pad layer 105. Also, to increase the heat emission efficiency, after forming a groove 115 by etching around an aperture of a light emitting region of the active layer 112, an outer wall of the groove 115 can be deposited with a metal layer 114b. The metal layer 114b is also a heat emission path since it is joined to the metal pad layer 105 of the sub-mount 100.

However, the conventional technology requires complicated processes. For example, after manufacturing a laser device, the laser device must be joined to a sub-mount 100 following lifting from a substrate. That is, after sequentially forming a first distributed brag reflector (first DBR) layer 111, an active layer 112, a second distributed brag reflector (second DBR) layer 113, and a metal contact layer 114a on a substrate 110, the manufactured laser device is lifted and is mounted on a sub-mount 100. Accordingly, the manufacturing cost is high. Furthermore, since the first DBR layer 111, the active layer 112, and the second DBR layer 113 form a very thin multi-layer structure in which optical pumping occurs, the risk of damage when mounting the laser device on the sub-mount 100 is high, and the mechanical stability after mounting is also significantly reduced.

Also, in the structure of FIG. 1, the transformation efficiency of second harmonic generation (SHG) is reduced, since light reaching a SHG crystal 120 is in a dispersed state due to the long distance between the active layer 112 and the external mirror 130. This is because the frequency doubling SHG crystal 120 increases efficiency in proportion to an energy density of light.

Also, light generated by the active layer must proceed to the substrate 110. At this time, there is a significant loss of light due to free carrier absorption in the substrate 110, since the substrate 110 has a thickness of several hundred μm. If the ratio of optical energy between the first DBR layer 111 and the external mirror 130 is lowered, to reduce the loss of light due to the free carrier absorption, the SHG transformation efficiency of a SHG crystal 120 between the substrate 110 and the external mirror 130 is further reduced. This reduces the overall efficiency of the laser device.

Finally, it is very difficult to meet the resonance condition, since the substrate 110 and air are present between the external mirror 130 and the first DBR layer 111. Also, as the optical path is longer, a high precision concave surface of the external mirror 130 is required so that light reflected by the external mirror 138 can be correctly converged onto the first DBR layer 111.

### SUMMARY OF THE DISCLOSURE

The present invention may provide a cooling structure of a semiconductor light emitting device that can effectively cool the light emitting device and can be manufactured by a simple method, and a method of manufacturing the semiconductor light emitting device.

The present invention may also provide a semiconductor light emitting device comprising: a substrate; a thermal spreading layer formed on the substrate and patterned to have a plurality of patterns; a planarizing layer having a planarizing surface covering the thermal spreading layer; and a light emitting unit formed on the planarizing layer.

The thermal spreading layer is formed into a plurality of patterns having a straight line shape or a polygon shape with predetermined gaps between the patterns. The width of the patterns of the thermal spreading layer is in the range of approximately 0.1-100 μm, and the width of the gaps between the patterns of the thermal spreading layer is in the range of approximately 0.1-100 μm. The thermal spreading layer can be formed of a material selected from the group consisting of diamond, BN, AlN, GaN, SiC, BeO, SiN, ZnO, Al2O3, Au, Al, Ag, and Cu.

The planarizing layer can be formed by selectively growing AlAs or GaAs in the gaps between the patterns of the thermal spreading layer.

According to an aspect of the present invention, there is provided a semiconductor laser device comprising: a substrate; a thermal spreading layer formed on the substrate and patterned to have a plurality of patterns; a lower DBR layer formed on the thermal spreading layer; an active layer that is formed on the lower DBR layer and generates light having a predetermined wavelength; and an upper DBR layer formed on the active layer.

The thermal spreading layer is formed into a plurality of patterns having a straight line shape or a polygon shape with predetermined gaps between the patterns. The width of the patterns of the thermal spreading layer is in the range of approximately 0.1-100 μm, and the width of the gaps between the patterns of the thermal spreading layer is in the range of approximately 0.1-100 μm. The thermal spreading layer can be formed of a material selected from the group consisting of diamond, BN, AlN, GaN, SiC, BeO, SiN, ZnO, Al2O3, Au, Al, Ag, and Cu.

The semiconductor laser device can further comprise a planarizing layer having a planarizing surface covering the thermal spreading layer and interposed between the thermal spreading layer and the lower DBR layer. The planarizing layer can be formed by selectively growing the same material for forming the lower DBR layer in the gaps between the patterns of the thermal spreading layer. The planarizing layer can include at least one of AlAs and GaAs.

Also, the semiconductor laser device can further comprise a current blocking layer that is formed on the upper DBR layer and blocks current from entering the upper DBR layer; a current transfer layer that is formed on the current blocking layer and transfers current; and a current injecting layer that contacts the upper DBR layer vertically passing through a central portion of the current transfer layer and the current blocking layer.

According to another aspect of the present invention, there is provided a method of manufacturing a semiconductor light emitting device, comprising: patterning a thermal spreading layer formed on a substrate to have a plurality of patterns; selectively growing a planarizing layer to completely cover the thermal spreading layer in the gaps between the patterns of the thermal spreading layer; planarizing the planarizing layer; and forming a light emitting unit on the planarizing layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view illustrating a conventional cooling structure of a light emitting device;

FIG. 2 is a cross-sectional view illustrating a cooling structure of a semiconductor light emitting device according to the present invention;

FIG. 3 is a perspective view illustrating a cooling structure of a semiconductor light emitting device according to the present invention;

FIG. 4A is a graph showing a simulation result when a thermal spreading layer is not used;

FIG. 4B is a graph showing a simulation result when a thermal spreading layer is used;

FIGS. 5A through 5E are cross-sectional views illustrating a method of manufacturing a cooling structure of a semiconductor light emitting device according to the present invention;

FIG. 6A is a cross-sectional view illustrating the growth state of a planarizing layer when the width of a thermal spreading layer is excessively wide;

FIG. 6B is a cross-sectional view illustrating the growth state of a planarizing layer when the width of a thermal spreading layer is appropriate; and

FIG. 7 is a cross-sectional view illustrating the structure of a semiconductor laser device employing a cooling structure according to the present invention.

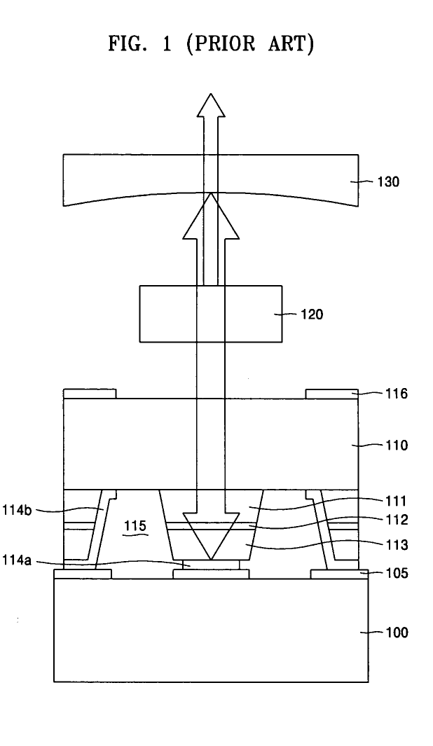

### DETAILED DESCRIPTION OF THE EXEMPLARY EMBODIMENTS

The present invention will now be described more fully with reference to the accompanying drawings in which exemplary embodiments of the invention are shown.

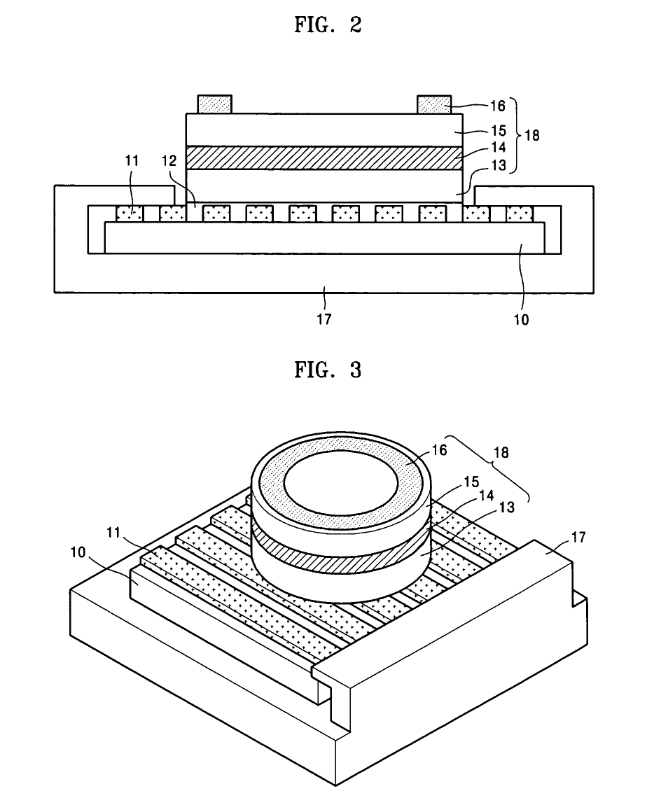

FIG. 2 is a cross-sectional view illustrating a cooling structure of a semiconductor light emitting device according to the present invention. Referring to FIG. 2, a semiconductor light emitting device comprises a substrate 10, a thermal spreading layer 11 formed on the substrate 10, a planarizing layer 12 that covers the thermal spreading layer 11 and has a planarized surface, and a light emitting unit 18 formed on the planarizing layer 12. As depicted in FIG. 2, the thermal spreading layer 11 is patterned to have gaps. Accordingly, the thermal spreading layer 11 has a wide thermal contact area with the light emitting unit 18. In this structure of the light emitting device, the components from the lower surface of the substrate to a portion of the upper surface of the thermal spreading layer 11 are packaged by a package 17. For example, the package 17 is formed of copper (Cu) to aid the emission of heat from the light emitting device.

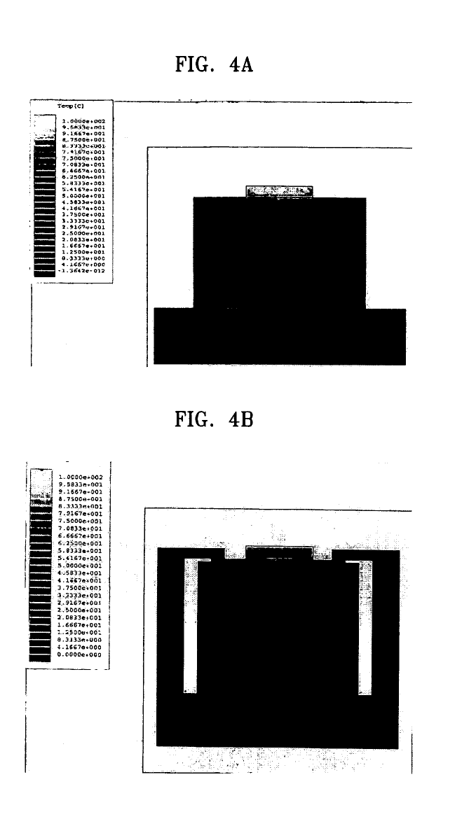

FIG. 3 is a perspective view illustrating a cooling structure of a semiconductor light emitting device according to the present invention. Referring to FIG. 3, the thermal spreading layer 11 formed on the substrate 10 can be structured as a plurality of straight lined patterns formed parallel to each other and separated by gaps. In this case, heat generated from the light emitting unit 18 is dissipated to the outside while flowing along the straight lined patterns. Also, the effect of dissipating heat is further increased by contacting the thermal spreading layer 11 and the package 17 formed of copper. In FIG. 3, the thermal spreading layer 11 is shown as a straight lined pattern as an illustrative example, and can also be formed in a variety of patterns having polygon shapes instead. The thermal spreading layer 11 can be formed of a material having high thermal conductivity, such as a dielectric or a metal. The dielectric can be diamond, BN, AlN, GaN, SiC, BeO, SiN, ZnO, Al2O3 and the metal can be Au, Al, Ag, or Cu.

The light emitting unit 18 can be a light emitting diode (LED) or a semiconductor laser. The light emitting unit 18 can include a lower distributed brag reflector (lower DBR) layer 13, an active layer 14, an upper DBR layer 15, and a metal contact 16. The active layer 14 is formed in a quantum well structure that generates light. The lower and upper DBR layers 13 and 15 have a multi-layer structure in which low refractive index layers and high refractive index layers are alternately stacked. This kind of semiconductor laser structure is well known to the industry, and therefore a detailed description is omitted.

According to the present invention, unlike in the conventional technology, the thermal spreading layer 11 and the light emitting unit 18 can be sequentially formed on the substrate 10. Therefore, a process for mounting the light emitting unit on a sub-mount by lifting from the substrate after forming the light emitting unit on the substrate is unnecessary. Accordingly, processes can be simplified and the manufacture of a mechanically stable light emitting device with no risk of damage during the manufacturing process is possible. Also, the cooling structure according to the present invention does not affect the emission efficiency of a semiconductor light emitting device, since the light is emitted directly from the upper DBR layer 15 without passing through the thick substrate. Also, as depicted in FIGS. 2 and 3, a high cooling effect can be obtained, since the contact area between the light emitting unit 18 and the thermal spreading layer 11 is enlarged by forming the thermal spreading layers 11 in many patterns having straight lines or polygon shapes. Therefore, heat generated in a high output light emitting device can be readily removed to the outside.

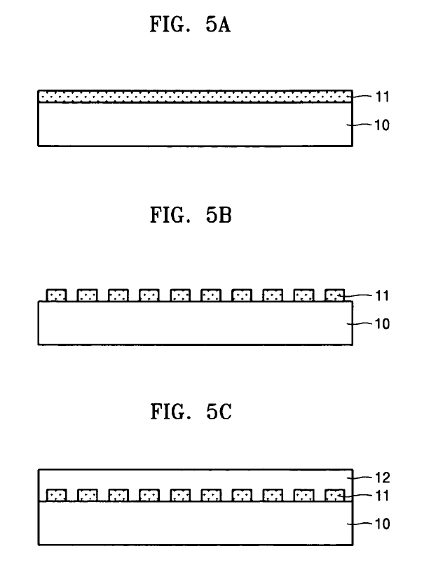

FIG. 4A is a graph showing a simulation result when a thermal spreading layer is not used, and FIG. 4B is a graph showing a simulation result when a thermal diffusion layer is used. Referring to FIG. 4A, when a thermal spreading layer 11 is not used, the entire light emitting device except the substrate and a portion of the lower DBR layer is heated to a very high temperature. However, as depicted in FIG. 4B, the portion of the light emitting device where the light is emitted is partly heated and a low overall temperature is maintained. Therefore, the use of the thermal spreading layer according to the present invention can effectively remove heat from a light emitting device.

The planarizing layer 12 facilitates the formation of the light emitting unit 18 on the thermal spreading layer 11 by providing a flat surface on the patterned thermal spreading layer 11. The planarizing layer 12 can be formed of the same material as the lowermost layer of the light emitting unit 18. For example, if the light emitting unit 18 is a semiconductor laser, the planarizing layer 12 can be formed of the same material as the lower DBR layer 13. As described above, the lower and upper DBR layers 13 and 15 have a multi-layered structure in which low refractive index layers and high refractive index layers are alternately stacked. Conventionally, the low refractive index layer is formed of AlAs and the high refractive index layer is formed of GaAs. That is, the lower and upper DBR layers 13 and 15 are formed by alternately stacking AlAs layers and GaAs layers. Therefore, when the light emitting unit 18 is a semiconductor laser, the planarizing layer 12 can be formed by selectively growing AlAs or GaAs in the gaps between the patterns of the thermal spreading layers 11.

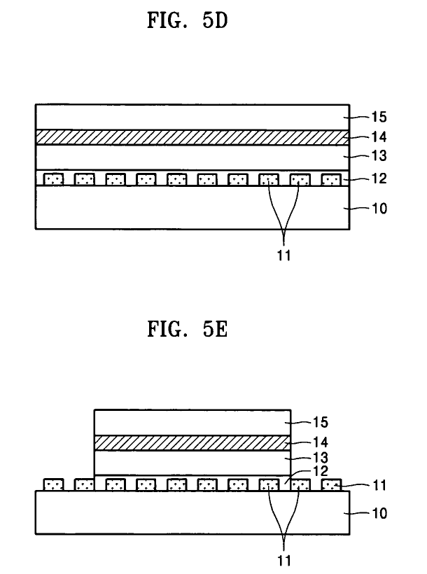

FIGS. 5A through 5E are cross-sectional views illustrating a method of manufacturing a cooling structure of a semiconductor light emitting device according to the present invention.

Referring to FIG. 5A, a thermal spreading layer 11 is deposited on the entire surface of a substrate 10. For example, the substrate 10 can be formed of GaAs. As described above, the thermal spreading layer 11 can be formed of a dielectric, such as diamond, BN, AlN, GaN, SiC, BeO, SiN, ZnO or Al2O3, or a metal, such as Au, Al, Ag, or Cu. Afterward, as depicted in FIG. 5B, the thermal spreading layer 11 formed on the entire surface of the substrate 10 is patterned to a predetermined shape. As described above, the thermal spreading layer 11 can be a plurality of parallel patterns in a straight lined shape or a plurality of patterns in a polygon shape.

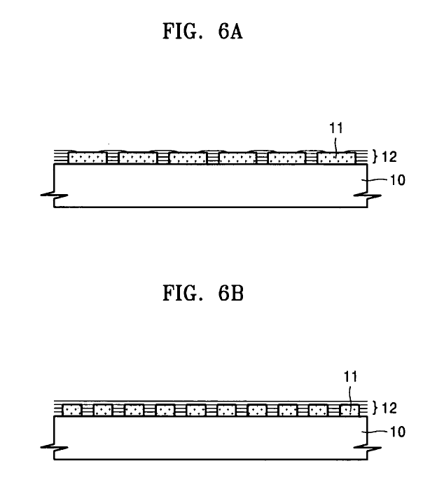

Referring to FIG. 5C, after crystal growing a planarizing layer 12 to completely cover the thermal spreading layer 11 beginning from the gaps between the thermal spreading layers 11, the upper surface of the planarizing layer 12 is planarized. As described above, if the light emitting unit 18 is a semiconductor laser, the planarizing layer 12 can be formed of AlAs or GaAs. At this time, as depicted in FIG. 6A, if the gaps between the patterns of the thermal spreading layer 11 are excessively wide, the planarizing layer 12 may not cover the upper surface of the patterns of the thermal spreading layers 11 while crystal growing of the planarizing layer 12. As a result, the surface of the thermal spreading layer 11 may not covered by the planarizing layer 12, or the surface of the planarizing layer 12 may be rough. Therefore, the width of the patterns of the thermal spreading layer 11 must be selected appropriately when patterning the thermal spreading layer 11, so that the planarizing layer 12 can be grown uniformly as depicted in FIG. 6B. In the present invention, the width of the patterns of the thermal spreading layer 11 is preferably approximately 0.1-100 μm. On the other hand, if the gap between the patterns of the thermal spreading layer 11 is excessively wide, a sufficient heat diffusion effect can not be obtained. In the present invention, the gap between the patterns of the thermal spreading layer 11 is preferably approximately 0.1-100 μm.

After forming the planarizing layer 12, as depicted in FIG. 5D, a light emitting unit 18 is formed on the planarizing layer 12. If a semiconductor laser is used as the light emitting unit 18, a lower DBR layer 13, an active layer 14, and an upper DBR layer 15 will be sequentially formed on the planarizing layer 12. As depicted in FIG. 5E, peripherals of the planarizing layer 12, the lower DBR layer 13, the active layer 14, and the upper DBR layer 15 can be etched until the thermal spreading layer 11 is exposed, according to the size and shape of the light emitting unit 18. Afterward, a metal contact 16 is deposited on the upper surface of the etched upper DBR layer 15.

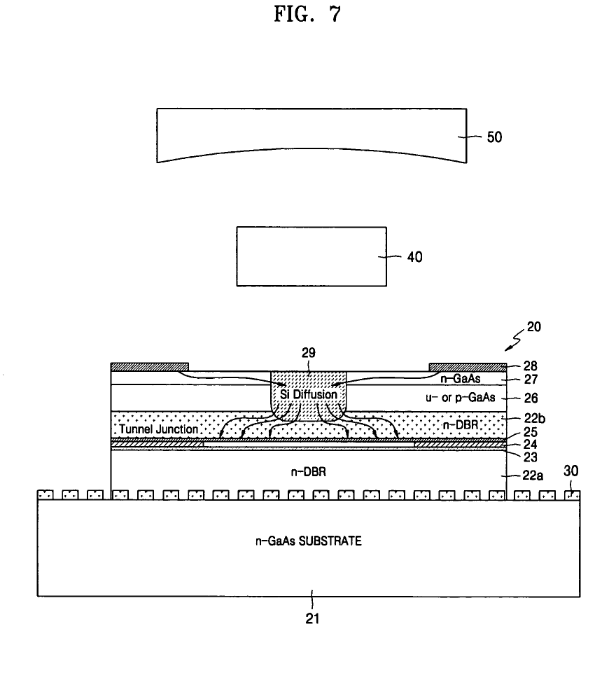

FIG. 7 is a cross-sectional view illustrating the structure of a semiconductor laser device employing a cooling structure according to the present invention.

Referring to FIG. 7, a high output laser device 20 including the cooling structure according to the present invention comprises a substrate 21, a thermal spreading layer 30 formed on the substrate 21, a lower DBR layer 22a formed on the thermal spreading layer 30, an active layer 23 formed on the lower DBR layer 22a, an upper DBR layer 22b formed on the active layer 23, a current blocking layer 26 formed on the upper DBR layer 22b, a current transfer layer 27 formed on the current blocking layer 26, and a current injecting layer 29 vertically formed from the center of the upper surface of the current transfer layer 27 to at least the upper surface of the upper DBR layer 22b. Also, an oxide layer 24 can further be formed for limiting the size of the aperture, which is the light emitting region of the active layer 23.

At this time, the current injecting layer 29 is very narrow relative to the aperture. Also, the current injecting layer 29 is formed to face a central portion of the aperture. According to the above structure, a current applied to a metal contact 28 is injected into the active layer 23 through the current injecting layer 29 along the arrows indicated in FIG. 7. Commonly, there are peaks of current density near both edges of the current injecting layer 29. However, the current is spread over a wide region of the active layer 23 while reaching the active layer 23 by passing through the narrow region of the current injecting layer 29. Therefore, an ideal current density distribution profile is obtained, in which the carrier distribution is relatively uniform over the whole region of the active layer 23. Accordingly, the laser device depicted in FIG. 7 is capable of oscillating in a single transverse mode. As a result, the manufacture of a high output single transverse mode oscillating laser device is possible, since the formation of an active layer having a diameter of approximately 30-200 μm is possible.

A tunnel junction layer 25 can also be included between the upper DBR layer 22b and the active layer 23, to aid the horizontal current distribution by relatively increasing resistance vertically. That is, the current density distribution in the active layer 23 can be made more uniform by increasing resistance vertically through the tunnel junction layer 25. The tunnel junction layer 25 has a structure in which a p+ type semiconductor layer and an n+ type semiconductor layer doped with a relatively high concentration are joined. A doping concentration of approximately 5×1018/cm3-5×1019/cm3 is preferably maintained, so that a relatively high resistance can be generated when electrons pass through the tunnel junction layer 25.

When the tunnel junction layer 25 is interposed between two same type semiconductor layers, it is possible to flow a current between the semiconductor layers due to a tunneling effect. Therefore, the manufacture of the lower and upper DBR layers 22a and 22b using the same type of semiconductor material is possible. That is, as depicted in FIG. 7, the lower and upper DBR layers 22a and 22b are all n-type DBR layers doped with an n-dopant. Also, the current transfer layer 27 is formed of an n-type semiconductor material, such as n-GaAs. In this case, the current blocking layer 26 can be formed of an undoped semiconductor material, such as u-GaAs, a p-type semiconductor material such as p-GaAs, or an insulating material. The current injecting layer 29 for injecting current into the active layer 23 from the current transfer layer 27 can be formed by diffusing an n-type dopant from the current transfer layer 27 to at least on an upper surface of the upper DBR layer 22b. The n-type dopant can be Si.

The laser device 20 can generate an output of at least a few hundred mW. Also, to further increase the output by increasing a gain region, as depicted in FIG. 7, an external mirror 50 can be included above the current transfer layer 27. Also, a second harmonic generation (SHG) crystal 40 that doubles the frequency of light generated by the active layer 23 can further be included between the current transfer layer 27 and the external mirror 50.

However, when the output is increased, more heat is generated by the active layer 23. In the case of the present invention, the heat generated from the active layer 23 can be effectively removed by adding the thermal spreading layer 30 between the substrate 21 and the lower DBR layer 22a. As described above, the planarizing layer can be regarded as a portion of the lower DBR layer 22a since the planarizing layer can be formed of the same material for forming the lower DBR layer 22a. Therefore, the planarizing layer is not shown in FIG. 7.

As described above, according to the present invention, heat generated by a high output light emitting device can be effectively removed using a thermal spreading layer provided between the substrate and the light emitting device. The cooling effect is high, since the contact area between the light emitting device and the thermal spreading layer is wide. Process steps can be simplified since there is no lifting or removal step, and a stable light emitting device can be manufactured since there is no risk of damaging the light emitting device during manufacture. The manufacturing method does not affect the emission efficiency of the semiconductor light emitting device.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor light emitting device comprising:
a substrate;
a thermal spreading layer formed on the substrate and patterned to have a plurality of patterns;
a planarizing layer having a planarizing surface covering the thermal spreading layer; and
a light emitting unit formed on the planarizing layer.

2. The semiconductor light emitting device of claim 1, wherein the thermal spreading layer is formed into a plurality of patterns having a straight line shape or a polygon shape with gaps between the patterns.

3. The semiconductor light emitting device of claim 2, wherein the width of the patterns of the thermal spreading layer is in the range of approximately 0.1-100 μm.

4. The semiconductor light emitting device of claim 2, wherein the width of the gaps between the patterns of the thermal spreading layer is in the range of approximately 0.1-100 μm.

5. The semiconductor light emitting device of claim 1, wherein the thermal spreading layer is formed of a material selected from the group consisting of diamond, BN, AlN, GaN, SiC, BeO, SiN, ZnO, Al₂O₃, Au, Al, Ag, and Cu.

6. The semiconductor light emitting device of claim 1, wherein the planarizing layer is formed by selectively growing AlAs or GaAs in the gaps between the patterns of the thermal spreading layer.

7. A semiconductor laser device comprising:
a substrate;
a thermal spreading layer formed on the substrate and patterned to have a plurality of patterns;
a lower DBR layer formed on the thermal spreading layer;
an active layer that is formed on the lower DBR layer and generates light; and
an upper DBR layer formed on the active layer.

8. The semiconductor laser device of claim 7, wherein the thermal spreading layer is formed into a plurality of patterns having a straight line shape or a polygon shape with gaps between the patterns.

9. The semiconductor laser device of claim 7, wherein the width of the patterns of the thermal spreading layer is in the range of approximately 0.1-100 μm.

10. The semiconductor laser device of claim 7, wherein the width of the gaps between the patterns of the thermal spreading layer is in the range of approximately 0.1-100 μm.

11. The semiconductor laser device of claim 7, wherein the thermal spreading layer is formed of a material selected from the group consisting of diamond, BN, AlN, GaN, SiC, BeO, SiN, ZnO, Al₂O₃, Au, Al, Ag, and Cu.

12. The semiconductor laser device of claim 11 further comprising a planarizing layer having a planarizing surface covering the thermal spreading layer and interposed between the thermal spreading layer and the lower DBR layer.

13. The semiconductor laser device of claim 12, wherein the planarizing layer is formed by selectively growing the same material for forming the lower DBR layer in the gaps between the patterns of the thermal spreading layer.

14. The semiconductor laser device of claim 11 further comprising:
a current blocking layer that is formed on the upper DBR layer and blocks current from entering the upper DBR layer;
a current transfer layer that is formed on the current blocking layer and transfers current; and
a current injecting layer that contacts the upper DBR layer vertically passing through a central portion of the current transfer layer and the current blocking layer.

15. A method of manufacturing a semiconductor light emitting device, comprising:
forming a thermal spreading layer on a substrate;
patterning the thermal spreading layer formed on the substrate to have a plurality of patterns.
selectively growing a planarizing layer to completely cover the thermal spreading layer in gaps between the patterns of the thermal spreading layer;
planarizing the planarizing layer; and
forming a light emitting unit on the planarizing layer.

16. The method of claim 15, wherein the thermal spreading layer is formed into a plurality of patterns having a straight line shape or a polygon shape with gaps between the patterns.

17. The method of claim 16, wherein the width of the patterns of the thermal spreading layer is in the range of approximately 0.1-100 μm.

18. The method of claim 16, wherein the width of the gaps between the patterns of the thermal spreading layer is in the range of approximately 0.1-100 μm.

19. The method of claim 15, wherein the thermal spreading layer is formed of a material selected from the group consisting of diamond, BN, AlN, GaN, SiC, BeO, SiN, ZnO, Al₂O₃, Au, Al, Ag, and Cu.

20. The method of claim 15, wherein the planarizing layer is formed by selectively growing AlAs or GaAs from the gaps between the patterns of the thermal spreading layer.
